(19) United States
(12) Patent Application Publication
(10) Pub. No.: US 2008/0246023 A1
(43) Pub. Date: Oct. 9, 2008

(54) Transistor Based on Resonant Tunneling Effect of Double Barrier Tunneling Junctions

(75) Inventors: Zhongming Zeng, Beijing (CN); Xiufeng Han, Beijing (CN); Jiafeng Feng, Beijing (CN); Tianxing Wang, Beijing (CN); Guanxiang Du, Beijing (CN); Feifei Li, Beijing (CN); Wenshan Zhan, Beijing (CN)

Correspondence Address: PERKINS COIE LLP, POST OFFICE BOX 1208, SEATTLE, WA, 98111-1208, US

(73) Assignee: INSTITUTE OF PHYSICS, CHINESE ACADEMY OF SCIENCES, Beijing (CN)

(21) Appl. No.: 11/663,684

(22) PCT Filed: Apr. 8, 2005
(86) PCT No.: PCT/CN05/00461

§ 371 Date: Mar. 23, 2007

(30) Foreign Application Priority Data
Sep. 24, 2004 (CN) 200410080016.4

(51) Int. Cl. H01L 29/06; H01L 27/082

(52) U.S. Cl. 257/25; 257/565; 257/E21.372

(57) ABSTRACT

The present invention relates to a transistor based on resonant tunneling effect of double barrier tunneling junctions comprising: a substrate, an emitter, a base, a collector and a first and a second tunneling barrier layers; wherein the first tunneling barrier layer is located between the emitter and the base, and the second tunneling barrier layer is located between the base and the collector; furthermore, the junction areas of the tunneling junctions which are formed between the emitter and the base and between the base and collector respectively are 1 μm²˜10000 μm²; the thickness of the base is comparable to the electron mean free path of material in the layer; the magnetization orientation is unbounded in one and only one pole of said emitter, base and collector. Because the double-barrier structure is used, it overcomes the Schottky potential between the base and the collector. Wherein the base current is a modulating signal, the collector signal is modulated to be similar to the base current's modulating mode by changing the magnetization orientation of the base or the collector, i.e., the resonant tunneling effect occurs. An amplified signal can be obtained under the suitable conditions.

### TECHNICAL FIELD

The present invention relates to a kind of solid-state switching and amplifying devices, i.e., transistor, more particularly, the present invention relates to a spin transistor device based on resonant tunneling effect of double barrier tunneling junctions.

### BACKGROUND ART

Since the giant magnetoresistance (GMR) effect was discovered in magnetic multilayers in 1988, great progress has been made in the researches and applications in physics and materials science. In 1993, Johnson [M. Johnson, Science 260 (1993) 320] presented a “ferromagnetic metal/nonmagnetic metal/ferromagnetic metal” sandwiched all-metal spin transistor which was composed of one ferromagnetic metal emitter, a nonmagnetic metal base with thickness smaller than spin diffusion length and another ferromagnetic metal collector. FIG. 1 is a schematic diagram of this all-metal spin transistor. Compared with Si semiconductor devices, this all-metal spin transistor has comparable speed, 10-20 times lower power consumption and about 50 times higher density. Moreover, this all-metal spin transistor is radiation-resistive, having memory function and can be used to form various kinds of logic circuits, processors and etc. of quantum computers in future. Later, IBM experimental group presented a spin transistor based on single barrier magnetic tunneling junction whose structure is: metal (emitter)/aluminum oxide/ferromagnetic metal (base)/semiconductor (collector). However, this kind of transistors has following shortcomings due to the Schottky potential produced between base and collector: □ lacking of the control of base-collector potential; □ high leakage current under low emitter-base voltage. □ comparatively low collector current. In 1997, Zhang [X. D. Zhang, Phys. Rev. B 56 (1997) 5484] theoretically predicted the tunnel magnetoresistance (TMR) oscillation phenomenon existing in magnetic double barrier tunneling junctions. In 2002, S. Yuasa [S. Yuasa, Science 297 (2002) 234] discovered the spin-polarized resonant tunneling phenomenon in single barrier magnetic tunneling junction. A resonant tunneling spin transistor fabricated by using the resonant tunneling effect of double barrier tunneling junctions can overcome the above-mentioned problems and have following advantages: high collector current; alterable base-collector voltage; comparatively low leakage current; and can be used in magnetic sensitive switches, current amplifying devices, oscillating devices and etc. However, because there were seldom researches on double barrier tunneling junctions and it is very difficult to fabricate perfect double barrier tunneling junctions, there has not been any spin transistor device based on resonant tunneling effect of double barrier tunneling junctions until now.

### DISCLOSURE OF THE INVENTION

An object of the present invention is to overcome the following defects of existing spin transistors based on single barrier magnetic tunneling junction: lacking of the control of base-collector potential, high leakage current under low emitter-base voltage and comparatively low collector current; thereby to provide a transistor based on resonant tunneling effect of double barrier tunneling junctions which has high collector current, alterable base-collector voltage, at the same time, has comparatively low leakage current and can be used in magnetic sensitive switches, current amplifying devices and oscillating device.

The object of the present invention is achieved as follows:

As shown in FIG. 2, a transistor based on resonant tunneling effect of double barrier tunneling junctions provided by the present invention comprises: a substrate 1, an emitter 3, a base 5, a collector 7 and a first tunneling barrier layer 4, wherein the first tunneling barrier layer 4 is located between the emitter 3 and the base 5; which is characterized in that: further comprises a second tunneling barrier layer 6; the second tunneling barrier layer 6 is located between the base 5 and the collector 7; furthermore, the junction areas of the tunneling junctions which are formed between the emitter 3 and the base 5 and between the base 5 and collector 7 respectively are 1 μm²˜10000 μm²; the thickness of said base 5 is comparable to the electron mean free path of material in the layer; the magnetization orientation is unbounded in one and only one pole of said emitter 3, base 5 and collector 7, i.e., the magnetization orientation of the layer can be altered by an external magnetic field.

Said substrate may be made from either insulator materials or non-insulator materials or semiconductor materials; said insulator materials include: Al₂O₃, SiO₂ and Si₃N₄, and the thickness of the substrate is in the range from 0.3 mm to 5 mm.

Said non-insulator materials include: Cu, Al.

Said semiconductor materials include: Si, Ga, GaN, GaAs, GaAlAs, InGaAs or InAs.

In the above-mentioned technical solution, an insulator layer 2 is further provided on the substrate when the substrate is made of a non-insulator material or a semiconductor material, and the thickness of the insulator layer 2 is 10-500 nm. Said insulator layer 2 comprises: aluminum oxide (Al₂O₃), silicon dioxide (SiO₂), silicon nitride (Si₃N₄) whose thickness is 50˜500 nm.

In the above-mentioned technical solution, a conductive layer 8 is further provided, which is located on the emitter 3, the base 5 and the collector 7. Meanwhile, the conductive layer 8 can also be used as protective layer. The conductive layer 8 comprises: gold, platinum, silver, aluminum, tantalum, etc. or other anti-oxidized metallic conductive materials, being 0.5˜10 nm in thickness.

In the above-mentioned technical solution, said emitter 3 comprises: either ferromagnetic materials (FM), semimetal magnetic materials (HM), magnetic semiconductive materials (MSC) or organic magnetic materials (OM), semiconductive materials (SC), nonmagnetic metal materials (NM) or metal Nb, etc. and Cu—O series superconductive materials (SP), such as YBa₂Cu₃O₇, etc., whose thickness is 2 nm˜20 nm.

In the above-mentioned technical solution, said base 5 comprises: either ferromagnetic materials (FM), semimetal magnetic materials (HM), magnetic semiconductor materials (MSC) or organic magnetic materials (OM), nonmagnetic metal materials (NM), semiconductor materials (SC); the thickness of the base 5 is 2 nm˜20 nm.

In the above-mentioned technical solution, said collector 7 comprises: either ferromagnetic materials (FM), semimetal magnetic materials (HM), magnetic semiconductive materials (MSC) or organic magnetic materials (OM), nonmagnetic metal materials (NM), semiconductive materials (SC); the thickness of the collector 7 is 2 nm˜20 nm.

Said ferromagnetic materials include: 3d transition magnetic metals such as Fe, Co, Ni, etc., rare-earth metals such as Sm, Gd, Nd, etc., and ferromagnetic alloys such as Co—Fe, Co—Fe—B, Ni—Fe, Gd—Y, etc.

In the above-mentioned technicalsolution, the direction of ferromagnetic magnetization can be pinned by an antiferromagnetic layer which can be composed of the alloys of Ir, Fe, Rh, Pt or Pd and Mn or other antiferromagnetic materials such as CoO, NiO, PtCr, etc.

Said semimetal magnetic materials (HM) include: Heussler alloys, such as Fe₃O₄, CrO₂, La_{0.7}Sr_{0.3}MnO₃ and Co₂MnSi, etc.

Said nonmagnetic metal materials (NM) include: Au, Ag, Pt, Cu, Ru, Al, Cr or/and their alloys.

Said magnetic semiconductor materials (MSC) include: Fe, Co, Ni, V, Mn-doped ZnO, TiO₂, HfO₂ and SnO₂, also include: Mn-doped GaAs, InAs, GaN and ZnTe.

Said organic magnetic materials (OM) include dicyclopentadiene metal macromolecule organic magnetic materials and manganese stearate.

Said semiconductor materials (SC) include: Si, Ga, GaN, GaAs, GaAlAs, InGaAs or InAs.

In the above-mentioned technical solution, said first tunneling barrier layer 4 and second tunneling barrier layer 6 are made of insulator materials which include insulating film of metal oxide, insulating film of metal nitride, insulating film of organic or inorganic material, diamond-like film, or EuS; the thickness of the first tunneling barrier layer is 0.5˜3.0 nm; the thickness of the second tunneling barrier layer is 0.5˜4.0 nm; and the thickness and materials of these two tunneling barrier layers can be same or different.

Metals of said insulating film of metal oxide and insulating film of metal nitride are chosen from metal elements Al, Mg, Ta, Zr, Zn, Sn, Nb and Ga.

The thickness of the base in the structure should be comparable to the electron mean free path of material in the layer, thereby the electron spin phase memory will be maintained because the electrons are affected by a relatively weak scattering effect in the base 5 when they tunnel from the emitter to the collector.

Comprised as above, the transistor based on resonant tunneling effect of double barrier tunneling junctions operates according to the following principle.

Take FIG. 3 as an example to elucidate the principle. So long as the emitter 3, the base 5 and the collector 7 are grounded, the emitter 3, the base 5, the collector 7, the first tunneling barrier layer 4 and the second tunneling barrier layer 6 will be in a thermal equilibrium state. FIG. 4 is a schematic diagram of the electron resonant tunneling of double barrier tunneling junctions for Embodiment 1, showing the tunneling processes of the tunneling electrons in two states under which the magnetization orientations of the emitter 3 and the collector 7 are parallel or antiparallel. In parallel state, the majority tunneling electrons in the emitter 3 with spinning orientations being the same as the magnetization orienitation of the collector 7 can tunnel through the barriers and the middle metal layer while the minority spinning electrons with spinning orientation opposite to the magnetization orientation of the collector 7 or the electrons with spinning orientations reversed due to impurity scattering cannot tunnel into the collector 7, at this time, there is comparatively high current flowing through the collector 7; while in antiparallel state, only the minority tunneling electrons with spinning orientations being the same as the magnetization orientation of the collector 7 can tunnel into the collector 7 while the majority tunneling electrons with spinning orientations opposite to the magnetization orientation of the collector 7 cannot tunnel into the collector 7, at this time, there is comparatively low current flowing through the collector 7. At the same time, the magnitude of the current of the collector 7 can be modulated by changing the magnetization orientation of the collector 7, because the magnetization orientation of the emitter 3 is fixed while the magnetization orientation of the collector 7 can be changed by a magnetic field. The forming process is as follows. The base current is a modulating signal, the signal of the collector 7 is modulated to be similar to the modulating mode of the base current by changing the magnetization orientation of the collector 7, i.e., the resonant tunneling effect occurs, and an amplified signal will be obtained under the suitable conditions.

A fabrication method of the transistor based on resonant tunneling effect of double barrier tunneling junctions provided by the present invention includes the following steps:

(1) By using a magnetron sputtering equipment or other film-fabricating equipment, the base 5 is fabricated on silicon substrate 1, comprising either a 4 nm-thick nonmagnetic metallic layer (NM), or a semiconductor layer (SC) or a layer of magnetic materials (FM, HM, MSC and OM);

(2) Then, the first tunneling barrier layer 4 and the second tunneling barrier layer 6 are formed on the base 5;

(3) The emitter 3 and the collector 7, made of layers of magnetic materials (including ferromagnetic materials FM, or semimetal magnetic materials HM, or magnetic semiconductive materials MSC, organic magnetic materials OM), are formed on the tunneling barrier layer 4 and 6;

(4) The emitter 3 and the collector 7 are made to have different reverse fields by using magnetic materials with different coercive forces or by controlling the relative size of the junction areas and shapes of the emitter 3 and the collector 7 through using micro-fabrication technique, thereby the magnetization orientation of one magnetic electrode is relatively fixed while the reverse of the magnetization orientation of another magnetic electrode is comparatively unbounded;

(5) Finally, a conductive layer 8 made of anti-oxidized metals gold or platinum, etc., is located on the base 5, the emitter 3 and the collector 7.

The advantages of the present invention are in that:

The transistor device based on double barrier tunneling junctions of the present invention overcomes the Schottky potential produced between a base and a collector because a double-barrier structure is used. The transistor has comparatively low leakage current and comparatively high collector current. At the same time, devices based on this kind of structures have certain current or voltage gain, i.e., input of small signal can produce comparatively large output. Wherein, the base current is a modulating signal, the collector signal is modulated to be similar to the base current's modulating mode by changing the magnetization orientation of base or collector, i.e., the resonant tunneling effect occurs, and an amplified signal can be obtained under the suitable conditions.

### BRIEF DESCRIPTION OF THE DRAWINGS

FIG. 1 is an all-metal spin transistor based on “ferromagnetic metal/nonmagnetic metal/ferromagnetic metal” structure

FIG. 2 is a schematic diagram of the structure of a transistor based on resonant tunneling effect of double barrier tunneling junctions of the present invention

FIG. 3a is a sectional view of the transistor's structure of Embodiments 1˜8 and 12 of the present invention

FIG. 3b is a sectional view of the transistor's structure of Embodiments 9 and 10 of the present invention

FIG. 3c is a sectional view of the transistor's structure of Embodiment 11 of the present invention

FIG. 3d is a sectional view of the transistor's structure of Embodiments 13˜16 of the present invention

FIG. 4a is a schematic diagram of the electron resonant tunneling of double barrier tunneling junctions of Embodiment 1

FIG. 4b is a schematic diagram of the electron resonant tunneling of double barrier tunneling junctions of Embodiment 1

FIG. 5 is a schematic diagram of the electron resonant tunneling of double barrier tunneling junctions of Embodiment 2

FIG. 6 is a schematic diagram of the electron resonant tunneling of double barrier tunneling junctions of Embodiment 4

FIG. 7 is a schematic diagram of the electron resonant tunneling of double barrier tunneling junctions of Embodiment 5

FIG. 8 is a schematic diagram of the electron resonant tunneling of double barrier tunneling junctions of Embodiment 9

FIG. 9 is a schematic diagram of the electron resonant tunneling of double barrier tunneling junctions of Embodiment 10

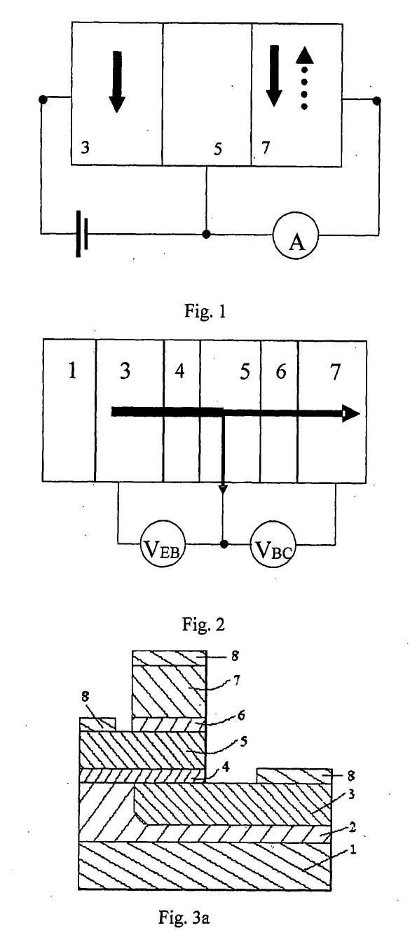

### LEGEND NOTE

| | | |
|---|---|---|
| substrate-1 | insulating layer-2 | emitter-3 |
| first tunneling barrier layer-4 | base-5 | second tunneling |
| collector-7 | conductive layer-8 | barrier layer-6 |

### SPECIFIC MODES FOR CARRYING OUT THE INVENTION

Hereinafter, the present invention will be further described in detail with reference to attached drawings and embodiments.

### Embodiment 1

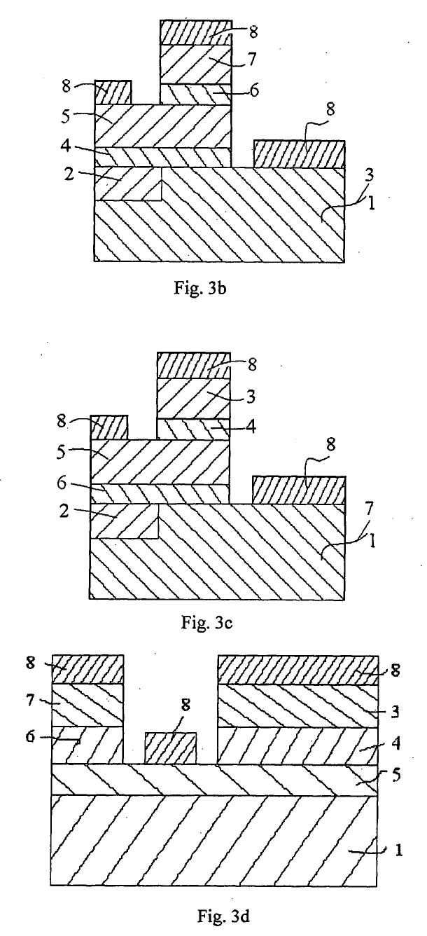

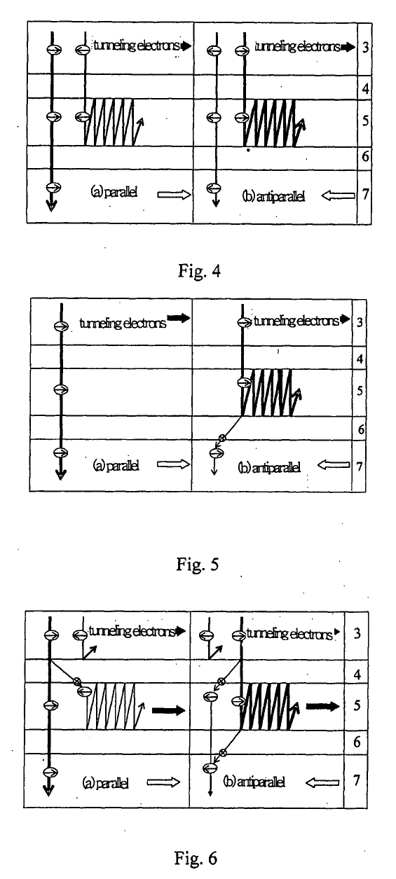

Referring to FIG. 3a, a spin transistor is provided based on the resonant tunneling effect of double barrier tunneling junctions of the present invention. In the spin transistor based on the resonant tunneling effect of double barrier tunneling junctions, a substrate 1 is made of a 0.4 mm-thick Si material, a 10 nm-thick insulating layer 2 made of SiO₂ is formed on the Si substrate 1, an emitter 3 is formed on the insulating layer 2, comprising a 12 nm-thick antiferromagnetic layer of Ir—Mn and an 8 nm-thick layer of Fe, wherein the antiferromagnetic layer of Ir—Mn is used to fix the magnetization orientation of the emitter 3; a first tunneling barrier layer 4 made of Al₂O₃ material is formed on the emitter 3, being 1 nm in thickness. Furthermore, an 8 nm-thick base 5 is formed on the first tunneling barrier layer 4, being made of nonmagnetic metal Cu. An Al₂O₃ layer is formed on the base 5, acting as a second tunneling barrier layer 6 with 1.6 nm in thickness; a collector 7 made of a layer of Co—Fe magnetic material is formed on the second tunneling barrier layer 6, being 8 nm in thickness, and the magnetization orientation of the collector 7 is unbounded and can be changed by an external magnetic field; a conductive layer 8 made of Pt or Au material is located on the emitter 3, the base 5 and the collector 7, and the thickness of the conductive layer 8 is 10 nm.

In the transistor of this embodiment, the junction areas of the tunneling junctions which are formed between the emitter 3 and the base 5 and between the base 5 and collector 7 respectively are 1 μm².

### Embodiment 2

Referring to FIG. 3a, a spin transistor is provided based on the resonant tunneling effect of double barrier tunneling junctions of the present invention. In the spin transistor based on the resonant tunneling effect of double barrier tunneling junctions, a substrate 1 is made of a 0.6 mm-thick Si material, a 100 nm-thick insulating layer 2 made of SiO₂ is formed on Si substrate 1, an emitter 3 is formed on the insulating layer 2, comprising a 15 nm-thick antiferromagnetic layer of Fe—Mn and a 4 nm-thick layer of a semimetal material La_{0.7}Sr_{0.3}MnO₃, wherein the magnetization orientation of the emitter 3 is fixed; a first tunneling barrier layer 4 made of SrTiO₃ material is formed on the emitter 3, being 1.0 nm in thickness; furthermore, a 4 nm-thick base 5 is formed on the first tunneling barrier layer 4, being made of a layer of a nonmagnetic metal material Ru; a SrTiO₃ layer is formed on the base 5, acting as a second tunneling barrier layer 6 with 1.3 nm in thickness; a collector 7 made of a layer of a semimetal material La_{0.7}Sr_{0.3}MnO₃ is formed on the second tunneling barrier layer 6, being 4 nm in thickness, and the magnetization orientation of the collector 7 is comparatively unbounded and can be changed by an external magnetic field; a conductive layer made of Pt or Au material is located on the emitter 3, the base 5 and the collector 7, and the thickness of the conductive layer 8 is 6 nm.

FIG. 5 is a schematic diagram of the electron resonant tunneling of double barrier tunneling junctions. In this kind of structures, nearly all the electrons tunnel into the collector 7 when the magnetization orientations of the emitter 3 and the collector 7 are parallel because the spin of the semimetal magnetic material La_{0.7}Sr_{0.3}MnO₃ can be polarized up to 100%, at this time, there is comparatively high current flowing through the collector 7. On the contrary, only a few tunneling electrons tunnel into the collector 7 by scattering or other effects when the magnetization orientations of the emitter 3 and the collector 7 are opposite, at this time, there is comparatively low current flowing through the collector 7. As the same as said principle of Embodiment 1, also by changing the magnetization orientation of the collector 7, the resonant tunneling of tunneling electrons between the emitter 3 and the collector 7 can be brought, and amplified current can be obtained for the collector 7 under the suitable conditions.

In the transistor of this embodiment, the junction areas of the tunneling junctions which are formed between the emitter 3/collector 7 and the base 5 are 100 μm².

### Embodiment 3

Referring to FIG. 3a, a spin transistor is provided based on the resonant tunneling effect of double barrier tunneling junctions of the present invention.

In the spin transistor based on the resonant tunneling effect of double barrier tunneling junctions, a substrate 1 is made of a 0.6 mm-thick Si material, a 300 nm-thick insulating layer 2 made of SiO₂ is formed on Si substrate 1, an emitter 3 is formed on the insulating layer 2, comprising a 4 nm-thick layer of a magnetic semiconductive material GaMnAs. The magnetization orientation of the emitter 3 is comparatively unbounded and can be changed by an external magnetic field; a first tunneling barrier layer 4 made of MgO material is formed on the emitter 3, being 1.0 nm in thickness. Furthermore, a 5 nm-thick base 5 is formed on the first tunneling barrier layer 4, being made of a layer of a nonmagnetic metal material Cr; a MgO layer is formed on the base 5, acting as a second tunneling barrier layer 6 with 1.3 nm in thickness; a collector 7 made of a layer of a magnetic semiconductive material GaMnAs is formed on the second tunneling barrier layer 6, being 8 nm in thickness, and a 20 nm-thick antiferromagnetic material PtCr is formed on the collector 7 to fix the magnetization orientation of the collector 7. A conductive layer made of Pt or Au material is located on the emitter 3, the base 5 and the collector 7, and the thickness of the conductive layer 8 is 6 nm.

In the transistor of this embodiment, the junction areas of the tunneling junctions which are formed between the emitter 3/collector 7 and the base 5 are 1000 μm².

### Embodiment 4

Referring to FIG. 3a, a spin transistor is provided based on the resonant tunneling effect of double barrier tunneling junctions of the present invention.

In the spin transistor based on the resonant tunneling effect of double barrier tunneling junctions, a substrate 1 is made of a 1 mm-thick Al₂O₃ material, an emitter 3 is formed on Al₂O₃ substrate 1, comprising a 15 nm-thick antiferromagnetic layer of Ir—Mn and an 8 nm-thick layer of an alloy material Co—Fe—B. The magnetization orientation of the emitter 3 is fixed; a first tunneling barrier layer 4 made of MgO material is formed on the emitter 3, being 1.8 nm in thickness. Furthermore, a 4 nm-thick base 5 is formed on the first tunneling barrier layer 4, being made of a layer of a magnetic material Co—Fe which has comparatively large coercive force; wherein the magnetization orientation is comparatively fixed and parallel to the magnetization orientation of the emitter 3. A MgO layer is formed on the base 5, acting as a second tunneling barrier layer 6 with 2.7 nm in thickness; a collector 7 made of a layer of a magnetic material Ni—Fe which has comparatively small coercive force is formed on the second tunneling barrier layer 6, being 8 nm in thickness, and the magnetization orientation of the collector 7 is comparatively unbounded and can be changed by an external magnetic field; a conductive layer made of Pt or Au material is located on the emitter 3, the base 5 and the collector 7, and the thickness of the conductive layer 8 is 6 nm.

The operating principle of this kind of spin transistors based on double barrier junctions is as follows. FIG. 6 is a schematic diagram of the electron resonant tunneling of double barrier tunneling junctions of this kind of transistors. Because the base material is a magnetic material, its transport property is spin-dependent. Therefore, when the magnetization orientations of the emitter 3, the base 5 and the collector 7 are in parallel state, the majority electrons in the emitter 3 with directions being the same as the magnetization orientations of the upper, the middle and the bottom electrodes (emitter 3, base 5, collector 7) will tunnel through the base 5 and the double barriers and transmit into the collector 7; while the minority electrons in the emitter 3 with directions opposite to the magnetization orientations of the upper, the middle and the bottom electrodes will be affected by a very strong scattering effect so that the electrons will not tunnel into the collector 7, however, in this case, the current of the collector 7 is still comparatively high; when the magnetization orientations of the collector 7 and the base 5 are opposite, although the majority electrons of the spin bands in the emitter 3 can tunnel through the first tunneling barrier layer, the electrons are effected by a strong scattering effect (corresponding to mirror-scattering) because their directions are opposite to the magnetization orientation of the collector 7, thereby the electrons will be localized in the middle base 5 and an oscillation will occur, only the minority tunneling electrons can tunnel through the second tunneling barrier layer and transmit into the collector 7 because spin flip occurs under the effect of impurity scattering or other inelastic scattering, at this time, the current of the collector 7 is comparatively low. As the same as the principle of the aforementioned embodiments, also by changing the magnetization orientation of the collector 7, the resonant tunneling of tunneling electrons between the emitter 3 and the collector 7 can be brought, and amplified current of the collector 7 can be obtained under the suitable conditions.

In the transistor of this embodiment, the junction areas of the tunneling junctions which are formed between the emitter 3/collector 7 and the base 5 are 10000 μm².

### Embodiment 5

Referring to FIG. 3a, a spin transistor is provided based on the resonant tunneling effect of double barrier tunneling junctions of the present invention.

In the spin transistor based on the resonant tunneling effect of double barrier tunneling junctions, a substrate 1 is made of a 1 mm-thick Si₃N₄ material, an emitter 3 is formed on Si₃N₄ substrate 1, comprising a 15 nm-thick antiferromagnetic layer of Ir—Mn and an 8 nm-thick layer of a semimetal material La_{0.7}Sr_{0.3}MnO₃. The magnetization orientation of the emitter 3 is fixed; a first tunneling barrier layer 4 made of SrTiO₃ material is formed on the emitter 3, being 1.0 nm in thickness. Furthermore, a 4 nm-thick base 5 is formed on the first tunneling barrier layer 4, being made of a layer of a semimetal material La_{0.7}Sr_{0.3}MnO₃; the magnetization orientation of the base 5 is also comparatively fixed and parallel to the magnetization orientation of the emitter 3. A SrTiO₃ layer is formed on the base 5, acting as a second tunneling barrier layer 6 with 1.3 nm in thickness; a collector 7 made of a layer of a semimetal material Co₂MnSi which has comparatively small coercive force is formed on the second tunneling barrier layer 6, being 4 nm in thickness, and the magnetization orientation of the collector 7 is comparatively unbounded and can be changed by an external magnetic field; a conductive layer made of Pt or Au material is located on the emitter 3, the base 5 and the collector 7, and the thickness of the conductive layer 8 is 6 nm.

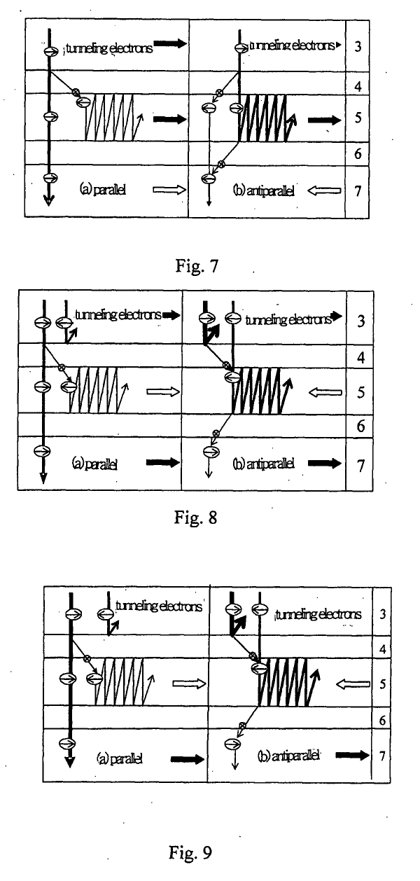

The operating principle of this kind of spin transistors based on double barrier junctions is similar to that of Embodiment 4. FIG. 7 is a schematic diagram of the electron resonant tunneling of double barrier tunneling junctions of this kind of transistors. Because the spin of the semimetal magnetic materials can be polarized up to 100%, when the magnetization orientations of the emitter 3, the base 5 and the collector 7 are parallel, nearly all the tunneling electrons will tunnel into the collector 7, at this time, there is comparatively high current flowing though the collector 7. On the contrary, when the magnetization orientations of the emitter 3, the base 5 and the collector 7 are antiparallel, only a few tunneling electrons will tunnel into the collector 7 through scattering or other effects, at this time, there is comparatively low current flowing through the collector 7. As the same as the aforementioned Embodiments, also by changing the magnetization orientation of the collector 7, the resonant tunneling of tunneling electrons between the emitter 3 and the collector 7 can be brought, and amplified current can be obtained for the collector 7 under the suitable conditions.

### Embodiment 6

Referring to FIG. 3a, a spin transistor is provided based on the resonant tunneling effect of double barrier tunneling junctions of the present invention. A substrate 1 is made of 1 mm-thick Si, a 500 nm-thick insulating layer 2 made of SiO₂ is formed on Si substrate 1, an emitter 3 is formed on the insulating layer 2, comprising a 15 nm-thick antiferromagnetic layer of Ni—Mn and a 4 nm-thick layer of a magnetic semiconductive material Co-doped ZnO. The magnetization orientation of the emitter 3 is fixed; a first tunneling barrier layer 4 made of ZrO₂ material is formed on the emitter 3, being 1.0 nm in thickness. Furthermore, a 4 nm-thick base 5 is formed on the first tunneling barrier layer 4, being made of a layer of a magnetic semiconductive material Co-doped ZnO; the magnetization orientation of the base 5 is comparatively unbounded and can be changed by an external magnetic field; a ZrO₂ layer is formed on the base 5, acting as a second tunneling barrier layer 6 with 1.3 nm in thickness; a collector 7 made of a 4-nm thick layer of a magnetic semiconductive material Co-doped ZnO and a 15 nm-thick antiferromagnetic layer of Ni—Mn is formed on the second tunneling barrier layer 6, and the magnetization orientation of the collector 7 is comparatively fixed and parallel to the magnetization orientation of the emitter 3; a conductive layer made of Pt or Ta material is located on the emitter 3, the base 5 and the collector 7, and the thickness of the conductive layer 8 is 6 nm.

FIG. 8 is a schematic diagram of the electron resonant tunneling of double barrier tunneling junctions of this kind of transistors. What is different with Embodiment 4 is: in Embodiment 4, it is by changing the magnetization orientation of the collector 7 to change the current of the collector 7; while in this embodiment, it is by changing the magnetization orientation of the base 5 to change the current of the collector 7 because the magnetization orientations of the emitter 3 and the collector 7 are comparatively fixed and only the magnetization orientation of the base 5 is unbounded. The operating principle is similar to Embodiment 4. Here the detailed operating process is overleaped.

### Embodiment 7

Referring to FIG. 3a, a spin transistor is provided based on the resonant tunneling effect of double barrier tunneling junctions of the present invention. A substrate 1 is made of 1 mm-thick GaAs, a 260 nm-thick insulating layer 2 made of SiO₂ is formed on GaAs substrate 1, an emitter 3 is formed on the insulating layer 2, comprising a 10 nm-thick antiferromagnetic layer of Ir—Mn and an 8 nm-thick layer of an organic magnetic material manganese stearate. The magnetization orientation of the emitter 3 is fixed; a first tunneling barrier layer 4 made of Al₂O₃ material is formed on the emitter 3, being 1.0 nm in thickness. Furthermore, a 4 nm-thick base 5 is formed on the first tunneling barrier layer 4, being made of a layer of an organic magnetic material manganese stearate; the magnetization orientation of the base 5 is comparatively unbounded and can be changed by an external magnetic field; a Al₂O₃ layer is formed on the base 5, acting as a second tunneling barrier layer 6 with 1.3 nm in thickness; a collector 7 made of a 4-nm thick layer of an organic magnetic material manganese stearate and a 10 nm-thick antiferromagnetic layer of Ir—Mn is formed on the second tunneling barrier layer 6, and the magnetization orientation of the collector 7 is comparatively fixed and parallel to the magnetization orientation of the emitter 3; a conductive layer made of Pt or Ta material is located on the emitter 3, the base 5 and the collector 7, and the thickness of the conductive layer 8 is 6 nm.

The operating principle is similar to Embodiment 6. Here the detailed operating process is overleaped.

### Embodiment 8

Referring to FIG. 3a, a spin transistor is provided based on the resonant tunneling effect of double barrier tunneling junctions of the present invention. A substrate 1 is made of 1 mm-thick GaAs, a 400 nm-thick insulating layer 2 made of SiO₂ is formed on GaAs substrate 1, an emitter 3 is formed on the insulating layer 2, comprising a 10 nm-thick antiferromagnetic layer of Ir—Mn, 4 nm-thick Co—Fe, 0.9 nm-thick Ru and a 4 nm-thick layer of a magnetic material Co—Fe—B, and the magnetization orientation of the emitter 3 is fixed; a first tunneling barrier layer 4 made of MgO material is formed on the emitter 3, being 1.8 nm in thickness. Furthermore, a 4 nm-thick base 5 is formed on the first tunneling barrier layer 4, being made of a layer of a magnetic material Co—Fe—B; the magnetization orientation of the base 5 is comparatively unbounded and can be changed by an external magnetic field; a MgO layer is formed on the base 5, acting as a second tunneling barrier layer 6 with 2.5 nm in thickness; a collector 7 made of a 4-nm thick layer of a magnetic material Co—Fe—B, 0.9 nm-thick Ru, 4 nm-thick Co—Fe and a 10 nm-thick antiferromagnetic layer of Ir—Mn is formed on the second tunneling barrier layer 6, and the magnetization orientation of the collector 7 is comparatively fixed and parallel to the magnetization orientation of the emitter 3; a conductive layer made of Pt or Ta material is located on the emitter 3, the base 5 and the collector 7, and the thickness of the conductive layer 8 is 6 nm.

It should be noted that Co—Fe/Ru/Co—Fe—B is a synthetic antiferromagnetic material, the antiferromagnetic material Ir—Mn and the synthetic antiferromagnetic material Co—Fe/Ru/Co—Fe—B are used in this embodiment to fix the magnetization orientation of the magnetic layers, and the use of this structure is favorable to increase the exchange bias field and thereby improve the transistor's performance. The operating principle is similar to Embodiment 6. Here the detailed operating process is overleaped.

### Embodiment 9

Referring to FIG. 3b, a spin transistor is provided based on the resonant tunneling effect of double barrier tunneling junctions of the present invention. In this spin transistor, a 120 nm-thick insulating layer 2 made of silicon dioxide (SiO₂) or other Al₂O₃, Si₃N₄ insulator materials is formed on a substrate 1 which comprises Si or GaAs semiconductive material, and this insulating layer is used to isolate the base 5 from the emitter 3, wherein the semiconductor substrate acts as the emitter 3; a first tunneling barrier layer 4 made of Al₂O₃ or MgO material is formed on the emitter 3, being 1.0 nm in thickness; furthermore, a base 5 made of a 6 nm-thick layer of a magnetic material Ni—Fe is formed on the first tunneling barrier layer 4, wherein the magnetization orientation of the Ni—Fe layer is unbounded and can be changed by an external magnetic field; a second tunneling barrier layer 6 made of Al₂O₃ or MgO material is formed on the base 5, being 1.6 nm in thickness; a 6-nm thick collector 7 made of a magnetic material Co—Fe—Ni is formed on the second tunneling barrier layer 6, and the magnetization orientation of this layer is pinned and then fixed by the antiferromagnetic layer of Fe—Mn. A conductive layer 8 made of Au or Pt material is located on the emitter 3, the base 5 and the collector 7, being 6 nm in thickness.

FIG. 9 is a schematic diagram of the electron resonant tunneling of double barrier tunneling junctions of this kind of transistors, showing the tunneling processes of the tunneling electrons in two states that the magnetization orientations of the emitter 3 and the collector 7 are parallel or antiparallel. In parallel state, the majority tunneling electrons in the emitter 3 with spinning orientations being the same as the magnetization orientation of the collector 7 can tunnel through the barriers and the middle base 5 while the minority spinning electrons with directions opposite to the magnetization orientation of the collector 7 or the electrons with spinning orientations reversed due to the impurity scattering cannot tunnel into the collector 7, at this time, there is comparatively high current flowing through the collector 7; while in antiparallel state, only the minority tunneling electrons with spinning orientations being the same as the magnetization orientation of the collector 7 can tunnel into the collector 7 while the majority tunneling electrons with spinning orientations opposite to the magnetization orientation of the collector 7 cannot tunnel into the collector 7, at this time, there is comparatively low current flowing through the collector 7. At the same time, the magnitude of the current of the collector 7 can be modulated by changing the magnetization orientation of the base 5 because the magnetization orientation of the collector 7 is fixed while the magnetization orientation of the base 5 can be changed by a magnetic field. The forming process is as follows. The current of the base 5 is a modulating signal, the signal of the collector 7 is modulated to be similar to the modulating mode of the current of the base 5 by changing the magnetization orientation of the base 5, i.e., the resonant tunneling effect occurs, and an amplified signal can be obtained under the suitable conditions.

### Embodiment 10

Referring to FIG. 3b, a spin transistor is provided based on resonant tunneling effect of double barrier tunneling junctions of the present invention. In this spin transistor, a 360 nm-thick insulating layer 2 which is made of silicon dioxide (SiO₂) or similar materials is formed on a substrate 1 which comprises Si or GaAs semiconductive material; an emitter 3 made of a 10 nm-thick superconductor material YBa₂Cu₃O₇ is formed on the insulating layer 2; a first tunneling barrier layer 4 made of Al₂O₃ material is formed on the emitter 3, being 1.0 nm in thickness; furthermore, a base 5 made of a 3 nm-thick layer of a magnetic material Sm is formed on the first tunneling barrier layer 4, wherein the magnetization orientation of the Sm layer is unbounded and can be changed by an external magnetic field or field induced by current; a second tunneling barrier layer 6 made of Al₂O₃ material is formed on the base 5, being 1.6 nm in thickness; a 6-nm thick collector 7 made of a magnetic material Gd—Y is formed on the second tunneling barrier layer 6, and the magnetization orientation of this layer is pinned and then fixed by the antiferromagnetic layer of Pd—Mn or Rh—Mn. A conductive layer 8 made of Au or Ta material is located on the emitter 3, the base 5 and the collector 7, being 5 nm in thickness.

The operating principle is similar to Embodiment 9. Here the detailed operating process is omitted.

### Embodiment 11

Referring to FIG. 3c, a spin transistor is provided based on resonant tunneling effect of double barrier tunneling junctions of the present invention.

In this spin transistor based on resonant tunneling effect of double barrier tunneling junctions, an insulating layer 2 made of silicon dioxide (SiO₂) or similar materials is formed on a substrate 1 which comprises Si or GaAs semiconductive material, and this insulating layer is used to isolate the base 5 from the collector 7, wherein the semiconductor substrate acts as the collector 7; a first tunneling barrier layer 4 made of Al₂O₃ or MgO material is formed on the collector 7, being 1.0 nm in thickness; furthermore, a base 5 made of a 4 nm-thick layer of a magnetic material Ni—Fe is formed on the first tunneling barrier layer 4, wherein the magnetization orientation of the Ni—Fe layer is unbounded and can be changed by an external magnetic field or the field induced by current; a second tunneling barrier layer 6 made of Al₂O₃ or MgO material is formed on the base 5, being 1.6 nm in thickness; a 6-nm thick emitter 3 made of a magnetic material Co—Fe is formed on the second tunneling barrier layer 6, and the magnetization orientation of this layer is pinned and then fixed by the antiferromagnetic layer of Pt—Mn. A conductive layer 8 made of Au or Pt material is located on the emitter 3, the base 5 and the collector 7, being 6 nm in thickness.

The operating principle is similar to Embodiment 9. Here the detailed operating process is omitted.

### Embodiment 12

Referring to FIG. 3a, a spin transistor is provided based on resonant tunneling effect of double barrier tunneling junctions of the present invention.

In this spin transistor based on resonant tunneling effect of double barrier tunneling junctions, a 100 nm-thick insulating layer 2 made of silicon dioxide (SiO₂) or similar materials is formed on a substrate 1 which comprises GaN or GaAs semiconductive material; a emitter 3 made of a 10 nm-thick nonmagnetic metal Cu is formed on the insulating layer 2; a first tunneling barrier layer 4 made of Al₂O₃ or MgO material is formed on the emitter 3, being 1.0 nm in thickness; furthermore, a base 5 made of a 5 nm-thick layer of a magnetic material CrO₂ is formed on the first tunneling barrier layer 4, wherein the magnetization orientation of the CrO₂ layer is unbounded and can be changed by an external magnetic field or the field induced by current; a second tunneling barrier layer 6 made of Al₂O₃ or MgO material is formed on the base 5, being 1.6 nm in thickness; a 6-nm thick collector 7 made of a semimetal material CrO₂ is formed on the second tunneling barrier layer 6, and the magnetization orientation of this layer is pinned and then fixed by the antiferromagnetic layer of Ni—Mn. A conductive layer 8 made of Au or Ta material is located on the emitter 3, the base 5 and the collector 7, being 5 nm in thickness.

### Embodiment 13

Referring to FIG. 3d, a spin transistor is provided based on the resonant tunneling effect of double barrier tunneling junctions of the present invention.

A base 5 made of 10 nm-thick GaAs is formed on a substrate 1 which comprises a semiconductive material InGaAs; first tunneling barrier layers 4 and 6 made of Al₂O₃ are formed on the base 5; an emitter 3 and a collector 7 made of 8 nm-thick Co—Fe are formed on the first tunneling barrier layers 4 and 6, being 6 nm in thickness; the relative size of the junction areas of the emitter 3 and the collector 7 is controlled by photo-lithography, etc. micro-fabrication techniques to make their reverse fields different, thereby the magnetic orientation of one magnetic electrode is comparatively fixed and that of another magnetic electrode is comparatively unbounded. A conductive electrode layer 8 made of 6 nm-thick Au material is located on the emitter 3, the base 5 and the collector 7. The distance between the emitter 3 and the collector 7 is smaller than 5 microns.

### Embodiment 14

Referring to FIG. 3d, a spin transistor is provided based on resonant tunneling effect of double barrier tunneling junctions of the present invention. A base 5 made of 10 nm-thick Co—Fe—B is formed on a substrate 1 which comprises Si semiconductive material; first tunneling barrier layers 4 and 6 made of MgO are formed on the base 5; an emitter 3 and a collector 7 made of a 15 nm-thick antiferroelectric material Ir—Mn and 6 nm-thick La_{0.7}Sr_{0.3}MnO₃ are formed on the first tunneling barrier layers 4 and 6, wherein the antiferroelectric material Ir—Mn is formed on La_{0.7}Sr_{0.3}MnO₃; the relative size of the junction areas of the emitter 3 and the collector 7 is controlled by photo-lithography. A conductive electrode layer 8 made of 6 nm-thick Au material is located on the emitter 3, the base 5 and the collector 7. In this kind of transistors, the distance between the emitter 3 and the collector 7 is smaller than 1 micron.

### Embodiment 15

Referring to FIG. 3d, a spin transistor is provided based on resonant tunneling effect of double barrier tunneling junctions of the present invention. A base 5 made of 4 nm-thick Co—Fe—B is formed on a substrate 1 which comprises Si semiconductive material; first tunneling barrier layers 4 and 6 made of AlN are formed on the base 5; an emitter 3 and a collector 7 made of a 15 nm-thick antiferroelectric material NiO and 6 nm-thick La_{0.7}Sr_{0.3}MnO₃ are formed on the first tunneling barrier layers 4 and 6, wherein the antiferroelectric material NiO is formed on La_{0.7}Sr_{0.3}MnO₃; the relative size of the junction areas of the emitter 3 and the collector 7 is controlled by photo-lithography, etc. micro-fabrication techniques. A conductive electrode layer 8 made of 6 nm-thick Au material is located on the emitter 3, the base 5 and the collector 7.

### Embodiment 16

Referring to FIG. 3d, a spin transistor is provided based on resonant tunneling effect of double barrier tunneling junctions of the present invention. A base 5 made of 4 nm-thick Co—Fe—B is formed on a substrate 1 which comprises an semiconductive material InAs; first tunneling barrier layers 4 and 6 made of EuS are formed on the base 5; an emitter 3 and a collector 7 made of a 15 nm-thick antiferroelectric material NiO and a 4 nm-thick magnetic semiconductor Mn-doped HfO₂ are formed on the first tunneling barrier layers 4 and 6, wherein the antiferroelectric material NiO is formed on the magnetic semiconductor material Mn-doped HfO₂; the relative size of the junction areas of the emitter 3 and the collector 7 are controlled by photo-lithography, etc. micro-fabrication techniques. A conductive electrode layer 8 made of 6 nm-thick Au material is located on the emitter 3, the base 5 and the collector 7.

Although the present invention has been fully described with reference to attached drawings, it should be noted that various alterations and modifications are possible for those of ordinary skill in the present field. Accordingly, the alterations and modifications without departing from the scope of the present invention should be included in the present invention.

1. A transistor based on resonant tunneling effect of double barrier tunneling junctions, which comprises: a substrate (1), an emitter (3), a base (5), a collector (7) and a first tunneling barrier layer (4), wherein the first tunneling barrier layer (4) is located between the emitter (3) and the base (5); which is characterized in that: further comprises a second tunneling barrier layer (6); the second tunneling barrier layer (6) is located between the base (5) and the collector (7); furthermore, the junction areas of the tunneling junctions which are formed between the emitter 3 and the base 5 and between the base 5 and collector 7 respectively are 1 μm²˜10000 μm²; the thickness of said base (5) is comparable to the electron mean free path of material in the layer; the magnetization orientation is unbounded in one and only one pole of said emitter (3), base (5) and collector (7).

2. The transistor based on resonant tunneling effect of double barrier tunneling junctions as set forth in claim 1, which is characterized in that: said substrate (1) is made of either insulator materials, non-insulator materials or semiconductive materials; the thickness of the substrate (1) is in the range from 0.3 mm to 5 mm; said insulator materials include: Al₂O₃, SiO₂ and Si₃N₄; said non-insulator materials include: Cu or Al; said semiconductor materials include: Si, Ga, GaN, GaAs, GaAlAs, InGaAs or InAs.

3. The transistor based on resonant tunneling effect of double barrier tunneling junctions as set forth in claim 2, which is characterized in thatfurther comprise an insulator layer (2) located on the substrate when the substrate (1) is made from a non-insulator material or a semiconductive material, and the thickness of the insulator layer (2) is 10˜500 nm; said insulator layer (2) includes: Al₂O₃ or Si₃N₄, being 50˜500 nm in thickness.

4. The transistor based on resonant tunneling effect of double barrier tunneling junctions as set forth in claim 1, which is characterized in that: further comprise a conductive layer (8), which is located on the emitter (3), the base (5) and the collector (7), and can be made of gold, platinum, silver, aluminum, tantalum or anti-oxidized metallic conductive materials, the conductive layer (8) is 0.5˜10 nm in thickness.

5. The transistor based on resonant tunneling effect of double barrier tunneling junctions as set forth in claim 1, which is characterized in that: said emitter (3), base (5) or collector (7) is made of ferromagnetic materials, semimetal magnetic materials, magnetic semiconductive materials, organic magnetic materials, semiconductive materials and nonmagnetic metal materials; said emitter (3) also can be made of metal Nb and a superconductor YBa₂Cu₃O₇, the thickness of the emitter (3), the base (5) or the collector (7) is 2 nm˜20 nm.

6. The transistor based on resonant tunneling effect of double barrier tunneling junctions as set forth in claim 5, which is characterized in that: said ferromagnetic materials include: 3d transition magnetic metals Fe, Co, Ni; rare-earth metals Sm, Gd or Nd; ferromagnetic alloys Co—Fe, Co—Fe—B, Ni—Fe or Gd—Y.

7. The transistor based on resonant tunneling effect of double barrier tunneling junctions as set forth in claim 5, which is characterized in that: said semimetal magnetic materials include: Heussler alloys Fe₃O₄, CrO₂, La_{0.7}Sr_{0.3}MnO₃ or Co₂ MnSi.

8. The transistor based on resonant tunneling effect of double barrier tunneling junctions as set forth in claim 5, which is characterized in that: said magnetic semiconductor materials include: Fe, Co, Ni, V, Mn-doped ZnO, TiO₂, HfO₂ and SnO₂, also include: Mn-doped GaAs, InAs, GaN or ZnTe.

9. The transistor based on resonant tunneling effect of double barrier tunneling junctions as set forth in claim 5, which is characterized in that: said organic magnetic materials include dicyclopentadiene metal macromolecule organic magnetic materials or manganese stearate.

10. The transistor based on resonant tunneling effect of double barrier tunneling junctions as set forth in claim 5, which is characterized in that: said nonmagnetic materials include: Au, Ag, Pt, Cu, Ru, Al, Cr or/and their alloys.

11. The transistor based on resonant tunneling effect of double barrier tunneling junctions as set forth in claim 5, which is characterized in that: said semiconductors include: Si, Ga, GaN, GaAs, GaAlAs, InGaAs or InAs.

12. The transistor based on resonant tunneling effect of double barrier tunneling junctions as set forth in claim 1, which is characterized in that: said first tunneling barrier layer (4) and second tunneling barrier layer (6) are made of insulator materials which include an insulating film of a metal oxide, an insulating film of a metal nitride, an insulating film of an organic or inorganic material, a diamond-like film or EuS; the thickness of the first tunneling barrier layer is 0.5˜3.0 nm; the thickness of the second tunneling barrier layer is 0.5˜4.0 nm; wherein the thickness and materials of these two tunneling barrier layers can be same or different.

13. The transistor based on resonant tunneling effect of double barrier tunneling junctions as set forth in claim 12, which is characterized in that: the metals of said insulating film of a metal oxide and insulating film of a metal nitride are chosen from metal elements Al, Ta, Zr, Zn, Sn, Nb, Ga or Mg.

14. The transistor based on resonant tunneling effect of double barrier tunneling junctions as set forth in claim 6, which is characterized in that: said ferromagnetic magnetization orientation can be pinned by an antiferromagnetic layer which which can be made of either the alloys of Ir, Fe, Rh, Pt or Pd and Mn, or antiferromagnetic materials CoO, NiO or PtCr.

15. The transistor based on resonant tunneling effect of double barrier tunneling junctions as set forth in claim 3, which is characterized in that: further comprise a conductive layer (8), which is located on the emitter (3), the base (5) and the collector (7), and can be made of gold, platinum, silver, aluminum, tantalum or anti-oxidized metallic conductive materials, the conductive layer (8) is 0.5˜10 nm in thickness.

16. The transistor based on resonant tunneling effect of double barrier tunneling junctions as set forth in claim 3, which is characterized in that: said emitter (3), base (5) or collector (7) is made of ferromagnetic materials, semimetal magnetic materials, magnetic semiconductive materials, organic magnetic materials, semiconductive materials and nonmagnetic metal materials; said emitter (3) also can be made of metal Nb and a superconductor YBa₂Cu₃O₇, the thickness of the emitter (3), the base (5) or the collector (7) is 2 nm˜20 nm.

17. The transistor based on resonant tunneling effect of double barrier tunneling junctions as set forth in claim 4, which is characterized in that: said emitter (3), base (5) or collector (7) is made of ferromagnetic materials, semimetal magnetic materials, magnetic semiconductive materials, organic magnetic materials, semiconductive materials and nonmagnetic metal materials; said emitter (3) also can be made of metal Nb and a superconductor YBa₂Cu₃O₇, the thickness of the emitter (3), the base (5) or the collector (7) is 2 nm˜20 nm.

18. The transistor based on resonant tunneling effect of double barrier tunneling junctions as set forth in claim 4, which is characterized in that: said first tunneling barrier layer (4) and second tunneling barrier layer (6) are made of insulator materials which include an insulating film of a metal oxide, an insulating film of a metal nitride, an insulating film of an organic or inorganic material, a diamond-like film or EuS; the thickness of the first tunneling barrier layer is 0.5˜3.0 nm; the thickness of the second tunneling barrier layer is 0.5˜4.0 nm; wherein the thickness and materials of these two tunneling barrier layers can be same or different.
